(19) United States
(12) Patent Application Publication
(10) Pub. No.: US 2008/0233269 A1
(43) Pub. Date: Sep. 25, 2008

(54) APPARATUS AND METHODS FOR APPLYING A LAYER OF A SPIN-ON MATERIAL ON A SERIES OF SUBSTRATES

(75) Inventors: Michael A. Carcasi, Austin, TX (US); Brian H. Head, Austin, TX (US)

Correspondence Address: WOOD, HERRON & EVANS, LLP (TOKYO ELECTRON), 2700 CAREW TOWER, 441 VINE STREET, CINCINNATI, OH, 45202, US

(73) Assignee: TOKYO ELECTRON LIMITED, Tokyo (JP)

(21) Appl. No.: 11/688,626

(22) Filed: Mar. 20, 2007

(51) Int. Cl. C23C 14/54

(52) U.S. Cl. 427/9; 118/58

(57) ABSTRACT

An apparatus and method for applying a fluid spin-on material on a surface of first and second substrates. A spin coating device is configured to dispense the fluid spin-on material to form a first layer on the surface of the first substrate. A metrology tool is configured to measure a first thickness profile of the first layer and generate data representing the first thickness profile. A processing unit is electrically coupled with the metrology tool and is configured to analyze the data received from the metrology unit and to determine a variation in the first thickness profile. The processing unit then determines an adjustment to an operational parameter of the spin coating device predicted to reduce a variation in a second thickness profile of a second layer subsequently formed by the spin coating device on a second substrate.

### FIELD OF THE INVENTION

The invention is related to semiconductor processing, in particular, to apparatus and methods for applying a layer of a spin-on material on a series of substrates.

### BACKGROUND OF THE INVENTION

Lithographic processes are widely used in the manufacture of semiconductor devices and other patterned structures. In track photolithographic processing used in the fabrication of semiconductor devices, the following sorts of processes may be performed in sequence: resist coating that coats a resist solution on a semiconductor wafer to form a resist film, exposure processing to expose a predetermined pattern on the resist film, heat processing to promote a chemical reaction within the resist film after exposure, developing processing to develop the exposed resist film, etc.

A conventional method that may be used for coating the resist solution on a wafer is a method referred to as spin coating. Spin coating is a method in which the wafer is suction-held on a disk-shaped support member known as a spin chuck. A solution-like resist is dispensed in essentially the center of the wafer, and the spin chuck rotates. Rotating disperses the resist solution supplied to the center of the wafer radially outward by centrifugal force to coat the entire surface of the wafer.

In order to suitably perform a predetermined track photolithographic process, it is important that the resist film coated on the wafer have a relatively uniform predetermined film thickness. Conventionally, this may be performed by measuring the film thickness of the resist film on the wafer before exposing a predetermined pattern on the resist film. If the allowable non-uniformity of the film thickness is exceeded, a correction is made, based on measurement results, to the rotation speed of the spin chuck in the spin coating device that applied the resist solution.

Because a flat wafer should be used to accurately measure film thickness, the calibration of the spin coating device is performed before the coating/developing system is put into a production mode. Therefore, conventional practice often requires an engineer highly skilled in the art of photolithography track processing to halt the system that photolithographicly processes the production wafer, introduce the first of a series of test wafers into the photolithographic processing system, form a resist film on the wafer, and then measure the film thickness on the test wafer before pattern exposure. Subsequently, based on the result of measuring film thickness of the resist film on the test wafer, if the allowed non-uniformity for film thickness is exceeded, the process engineer may manually make a correction to the rotational speed of the wafer (rotational speed of the spin chuck), for example, in the spin coating device in the system. The process engineer may then proceed with the measurement process with the next test wafer until either an allowable thickness is attained or a maximum number of test wafers is reached.

Given the complexity of resist chemistries, variations of casting and processing solvent systems, and the associated processing complexity generated by the shear number of available chemistries, the optimization of a spin-on chemistry for minimal non-uniformity of film thickness often requires an engineer highly skilled in arts of photolithography track processing. However, also given the usual highly symmetric nature of spin coating, the various parameters that affect film thickness uniformity may often be decoupled. Track process engineers call upon knowledge of parameter impact on uniformity of film thickness and a historical knowledge base of past experiences of a given chemistry and its conditions to minimize the non-uniformity.

What is needed, therefore, is an apparatus and process for assisting an operator of the coating/developing system in optimizing wafer uniformity, which does not require a highly skilled photolithography track processing engineer.

### SUMMARY OF THE INVENTION

The invention addresses these and other problems associated with the prior art by providing a method and apparatus for applying a fluid spin-on material on a surface of first and second substrates. A temperature of the first substrate is regulated and a first layer of the spin-on material is applied to the surface of the first substrate. The temperature of the first substrate is elevated to treat the spin-on coating. A first thickness profile of the first layer is then measured to determine a variation in the first thickness profile. An adjustment to an operational parameter that is predicted to reduce the variation in the first thickness profile is automatically determined. The adjustment is then made to the operational parameter to affect a second layer of the spin-on material applied to the surface of the second substrate. The adjustment to the operational parameter is automatically determined by numerically analyzing data received from the a metrology unit configured to measure the first thickness profile and utilizing parameter sensitivities derived from a design of experiment model to determine the adjustment to the operational parameter.

In an embodiment, the adjustment to the operational parameter is made by generating an electrical signal that represents the adjustment. The electrical signal is communicated to a device that regulates the temperature, applies the spin-on material, or elevates the temperature, and the operational parameter of the device is adjusted to reflect the communicated electrical signal.

In an alternate embodiment, the adjustment of the operational parameter is made by generating an electrical signal that represents the adjustment. The electrical signal is communicated to a display, which visually indicates the operational parameter and the adjustment to the operational parameter on the display. The operational parameter of a device that regulates the temperature, applies the spin-on material, or elevates the temperature is manually adjusted to reflect the visually indicated adjustment.

In some embodiments, a second thickness profile of the first layer is measured to determine a variation in the second thickness profile. The adjustment to the operational parameter of a device that regulates temperature, applies the spin-on material, or elevates the temperature is automatically determined to reduce the variation in the second thickness profile.

These and other advantages and features, which characterize the invention, are set forth in the claims annexed hereto and forming a further part hereof. However, for a better understanding of the invention, and of the advantages and objectives attained through its use, reference should be made to the drawings, and to the accompanying descriptive matter, in which there is described exemplary embodiments of the invention.

### BRIEF DESCRIPTION OF THE DRAWINGS

The accompanying drawings, which are incorporated in and constitute a part of this specification, illustrate embodiments of the invention and, together with a general description of the invention given above, and the detailed description given below, serve to explain the principles of the invention.

FIG. 1 is a plan view showing the general structure of a coating/developing system used to process substrates in accordance with an embodiment of the invention.

FIG. 2 is a front view of the coating/developing system in FIG. 1.

FIG. 3 is a rear view of the coating/developing system in FIG. 1.

FIG. 4 is a diagrammatic view of a resist coating unit, a temperature regulation device, and a metrology unit included in the coating/developing system in FIG. 1.

FIG. 5A is diagrammatic view of a thickness measurement tool of the metrology unit of FIG. 4 measuring coating thickness along a first diameter of a wafer.

FIG. 5B is diagrammatic view similar to FIG. 5A in which a coating thickness is measured along a second diameter of the wafer.

FIG. 6A is a diagrammatic cross-sectional view of a coating on a wafer in which the coating has a non-uniform thickness.

FIG. 6B is a diagrammatic cross-sectional view similar to FIG. 6A of another coating having a non-uniform thickness.

FIG. 7A is a diagrammatic cross-sectional view of a coating on a wafer in which the coating fails to conform to a wafer specification.

FIG. 7B is a graphical representation of a 1-D profile of the thickness of the coating of FIG. 7A taken across a diameter of the wafer.

FIG. 8A is a diagrammatic cross-sectional view of a coating on a wafer in which the coating thickness is asymmetrical across a diameter of the wafer.

FIG. 8B is a graphical representation of 1-D profiles of the thickness of the resist coating of FIG. 8A taken across two different diameters of the wafer.

FIG. 9 is a flow chart showing a process of optimizing coating thickness based on historical tendencies.

FIG. 10 is a flow chart showing a process of optimizing coating thickness based on a design of experiments.

### DETAILED DESCRIPTION

Due to the complexity of resist chemistries, variations of casting and processing solvent systems, and the associated processing complexity generated by the sheer number of available chemistries, the optimization of a spin on chemistry for minimal wafer coating non-uniformity often requires an engineer highly skilled in the arts of photolithography track processing. The track process engineers call upon a knowledge of a parameter impact on wafer uniformity from a historical knowledge base of past experiences of a given chemistry and its conditions to minimize wafer non-uniformity. This knowledge encompasses both the parameters related to the spin on coating process as well as parameters of the coating/developing system that may influence the spin on coating process.

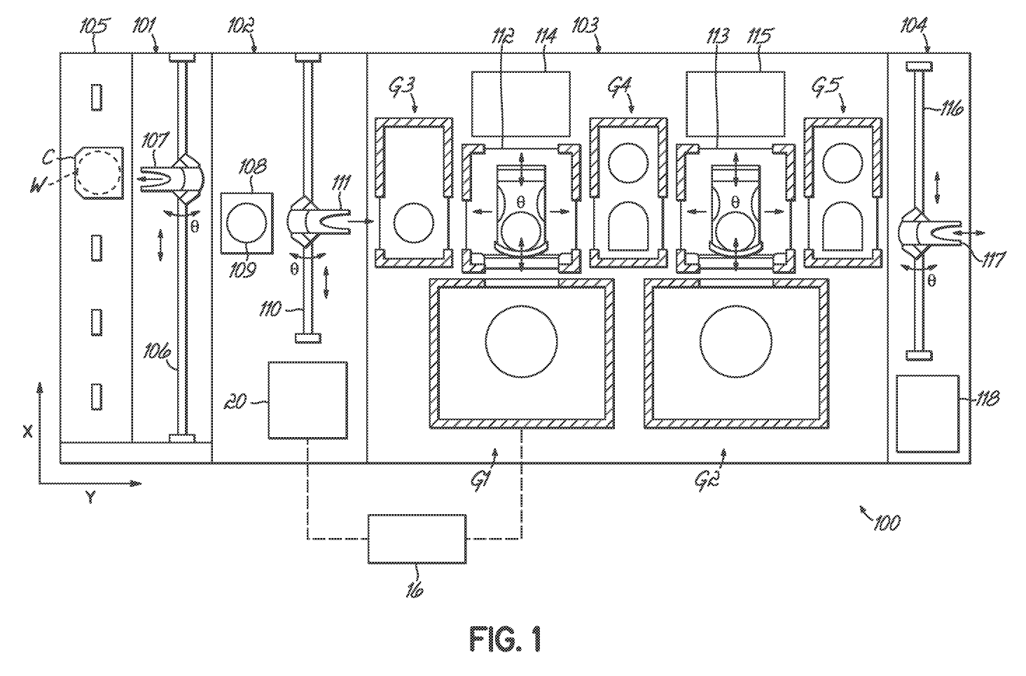

An exemplary coating/developing system 100, as shown in FIG. 1, may be constituted to integrally connect a cassette station 101, which transports a cassette typically holding 25 wafers W, for example, into the coating/developing system 100 from outside and which transports a wafer W to the cassette C; an inspection station 102 which performs a predetermined inspection on the wafer W; a processing station 103 with a plurality of types of processing devices disposed in stages to perform predetermined processes in a layered manner in the photolithography step; and an interface unit 104, provided adjacent to the processing station 103, for delivering the wafer W to an exposure device (not shown).

A cassette support stand 105 is provided at the cassette station 101; the cassette support stand 105 may freely carry a plurality of cassettes C in a row in the X direction (vertically, in FIG. 1). The cassette station 101 is provided with a wafer transporter 107 able to move on the transport path 106 in the X direction. The wafer transporter 107 may also move freely in the wafer array direction (Z direction; perpendicular) of the wafers W housed in the cassette C and can selectively access the wafer W vertically arrayed in the cassette C. The wafer transporter 107 may rotate around an axis (θ direction) in the particular direction, and may also access the inspection station's transfer unit 108.

A metrology unit 20 may be provided at the inspection station 102 adjacent to the cassette station 101. The metrology unit 20 is configured to receive the wafer W and detect a condition of a layer carried by the wafer, W. For example, the metrology unit 20 may be configured to measure coating thickness across a diameter of the wafer W.

The metrology unit 20 may be disposed at the negative X direction side (downward in FIG. 1) of the inspection station 102, for example. Disposed at the cassette station 101 side of inspection station 102 is the transfer unit 108 for transferring the wafer W from the cassette station 101. A carrying unit 109 for carrying the wafer W may be provided in the transfer unit 108. A wafer transporter 111 able to move on a transport path 110 in the X direction may be provided at the positive X direction side (upward in FIG. 1) of the metrology unit 20. The wafer transporter 110 also may move vertically and rotate freely in the θ direction, and may also access the transfer unit 108 in each processing device in a third processing device group G3 at the processing station 103 side.

A processing station 103 adjacent to the inspection station 102 is provided with a plurality of processing devices disposed in stages, such as five processing device groups G1-G5. The first processing device group G1 and the second processing device group G2 are disposed in sequence from the inspection station 102 side, at the negative X direction side (downward in FIG. 1) of the processing station 103. The third processing device group G3, fourth processing device group G4, and fifth processing device group G5 are disposed in sequence from the inspection station 102 side, at the positive X direction side (upward in FIG. 1) of the processing station 103. A first transport device 112 is provided between the third processing device group G3 and the fourth processing device group G4. The transport device 112 may transport the wafer W to access each device in the first processing device group G1, third processing device group G3, and fourth processing device group G4. A second transport device 113 transports the wafer W and selectively accesses the second processing device group G2, fourth processing device group G4, and fifth processing device group, G5.

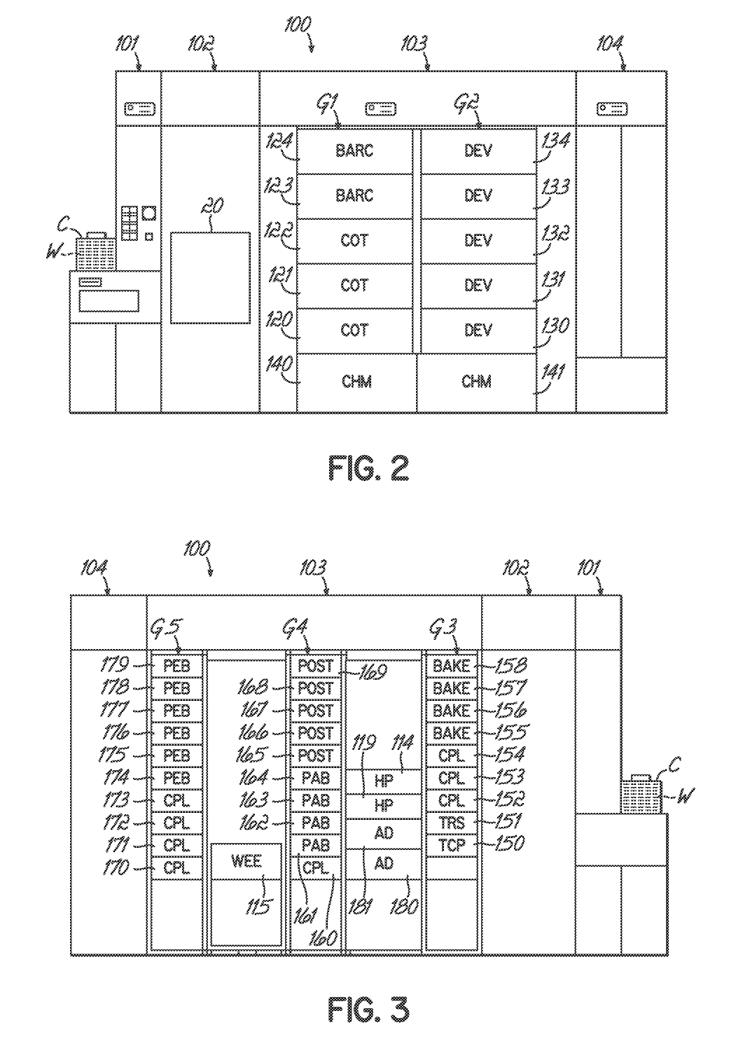

Referring now to FIG. 2, the first processing device group G1 stacks liquid processing devices that supply a predetermined liquid spin on material to the wafer W and process it. Devices such as spin coating devices 120, 121, and 122, which may apply a resist solution to the wafer W and form a resist film, and bottom coating devices 123 and 124, which form an anti-reflection film that prevents light reflection during exposure processing, may be arranged in five levels in sequence from the bottom. The second processing device group G2 stacks liquid processing devices such as developing devices 130-134, which supply developing fluid to the wafer W and develop it, in five levels in sequence from the bottom. Also, terminal chambers 140 and 141 are provided at the lowest stages of the first processing device group G1 and the second processing device group G2 in order to supply processing liquids to the liquid processing devices in the processing device groups G1 and G2.

Also, as shown in FIG. 3, for example, the third processing device group G3 stacks temperature regulation device 150, transition device 151 for transfer of the wafer W, high precision temperature regulation devices 152-154, which regulate the temperature of the wafer W under high precision temperature management, and high temperature heating devices 155-158, which heat the wafer W to high temperature, in nine levels in sequence from the bottom.

The fourth processing device group G4 stacks a high precision temperature regulation device 160, pre-baking devices 161-164 for heating the wafer W after resist coating processing, and post-baking devices 165-169, which heat the wafer W after developing, in ten levels in sequence from the bottom. Each of the pre-baking devices 161-164 and post-baking devices 165-169 includes a hotplate (not shown) for elevating the temperature of the wafer W and the layer on the wafer W.

The fifth processing device group G5 stacks a plurality of heating devices that heat the wafer W, such as high precision temperature regulation devices 170-173, and post-exposure baking devices 174-179 in ten levels in sequence from the bottom.

A plurality of processing devices may be disposed at the positive X direction side of the first transport device 112 as shown in FIG. 1. Adhesion devices 180 and 181 for making the wafer W hydrophobic and heating devices 119 and 114 for heating the wafer W are stacked in four levels in sequence from the bottom, as shown in FIG. 3, for example. A peripheral exposure device 115 for selectively exposing only the edge of the wafer W may be disposed at the positive X direction side of the second transport device 113 as shown in FIG. 1.

Provided in the interface unit 104 are a wafer transporter 117 that moves on a transport path 116 extending in the X direction as shown in FIG. 1 and a buffer cassette 118. The wafer transporter 117 can move in the Z direction and can rotate in the θ direction; and can transport the wafer W and access the exposure device (not shown) adjacent to the interface unit 104 and the buffer cassette 118 and the fifth processing device group G5.

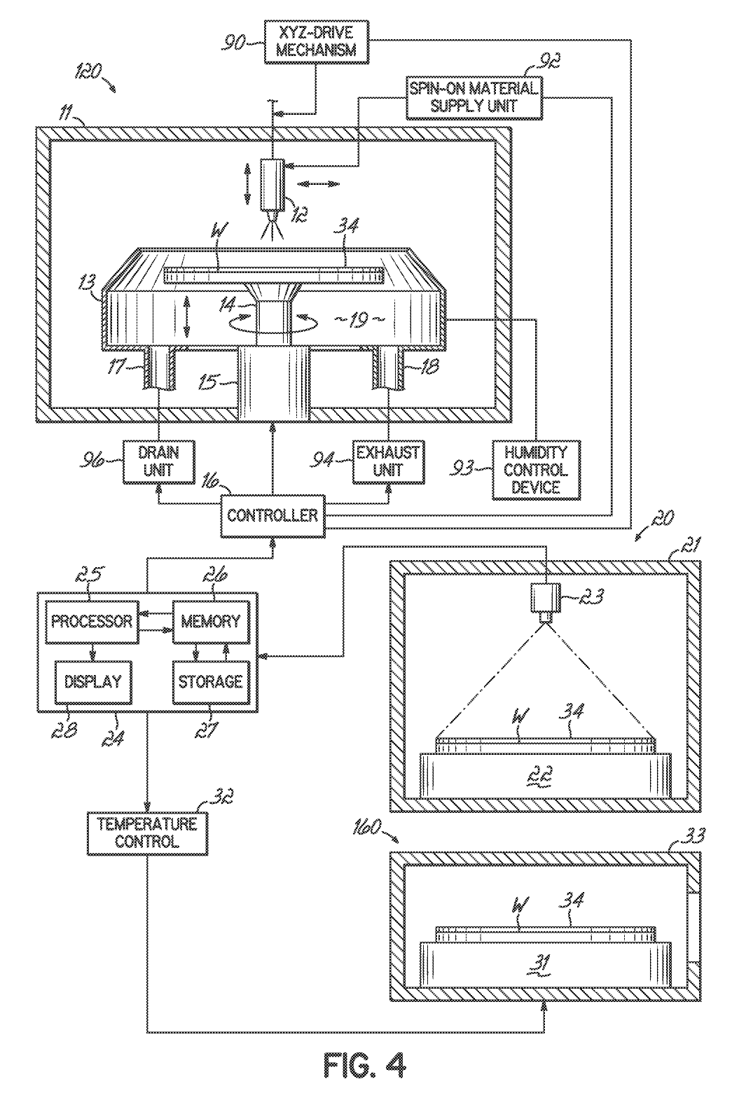

Wafers W are coated in the spin coating devices 120-122 which may be seen in greater detail in FIG. 4. The structure of the spin coating device 120, for example, may have a chamber wall 11. A substrate support, which has the form of a spin chuck 14 in the representative embodiment, is disposed inside the chamber wall 11. The spin chuck 14 has a horizontal upper surface on which the wafer W is supported during processing. A suction port (not shown) may be provided in its upper surface for securing the wafer W to the spin chuck 14 with suction.

The spin chuck 14 and the wafer W supported by the spin chuck 14 may be rotated at a variable angular velocity by a drive mechanism 15, which may be a stepper motor, etc. Additionally, a lift drive source, such as a cylinder, may be provided in the drive mechanism 15 so the spin chuck 14 may move vertically relative to the chamber wall 11. The drive mechanism may operate at two different angular velocities, one for the application of the spin-on material, and one for the reflow of the material on the substrate.

A dispenser, which has the form of a nozzle 12 in the representative embodiment, is adapted to dispense resist solution onto the wafer, W at a specified rate. The nozzle 12 is coupled to a supply unit 92 configured to control the temperature of and supply specific volume for a flow of a spin-on material, which may comprise a resist solution. A drive mechanism 90 may move the nozzle 12 in the plane of the wafer W, as well as normal to the surface of the wafer W, in order to adjust the position of the nozzle 12 relative to the wafer W. The nozzle 12 and/or the supply unit 92 may include a heater (not shown) for regulating the temperature of the liquid spin-on material.

A cup 13 bounding a processing space 19 may be provided about the periphery of the spin chuck 14 to capture and collect a majority of the liquid spin-on material ejected from the wafer W by centrifugal forces generated during rotation by the spin chuck 14. The spin chuck 14 supports and rotates (i.e., spins) the wafer W about its central normal axis relative to the cup 13, which is stationary. An exhaust port 18 communicates with the processing space 19 bounded by the cup 13. The processing space 19 is coupled by the exhaust port 18, which extends through the chamber wall 11, with a negative pressure-generating device 94, such as a vacuum pump. Operation of the negative pressure-generating device 94 continuously removes gaseous species at an exhaust rate, including but not limited to vapors released from layer 34 during processing, from the processing space 19 inside cup 13. The processing space 19 bounded by the cup 13, which contains a gaseous atmosphere, is also coupled by a drain port 17 with a drain unit 96, which disposes of liquid spin-on material collected by the cup 13 and drained from the processing space 19 through drain port 17.

A controller 16 is electrically connected to the drive mechanism 90, resist supply unit 92, exhaust unit 94, drain unit 96, and the chuck drive mechanism 15. The controller 16 is configured to respond to changes in parameters for the various components, which in turn adjust the performance of the spin coating device 120. The controller 16 may be connected to a processing unit 24, which is configured to provide the controller 16 with modified parameter information to automatically adjust the performance of the spin coating device 120. The processing unit 24 may receive input from the metrology unit 20 that is representative of the condition of the layer 34 carried on the wafer W.

The processing unit 24 may also be electrically connected to a temperature controller 32 for the temperature regulation device 160. The temperature controller 32 may also be configured to respond to changes in parameters for a chill plate 31, which in turn affect the coating thicknesses produced by the spin coating device 120. The chill plate 31 may be electrically connected to the temperature controller 32, which is in turn connected to the processing unit 14. A wafer W may be delivered to the temperature regulation device 160 where it is supported above a chill plate 31. The wafer may be delivered to the temperature regulation device 160 before or after the spin coating device 120. Operational parameters such as chill plate temperature and chill time may affect the coating thickness of layer 34 across the diameter of the wafer. For example, a wafer temperature that is greater than the temperature of the spin-on material may create a concave profile. Similarly, a wafer temperature that is less than the temperature of the spin-on material may create a convex profile. A chill time that is too short may lead to across wafer thermal non-uniformities causing non-uniform profiles.

The metrology unit 20, as shown in FIG. 4, may be configured to measure the coating thickness of layer 34 across a diameter of the wafer W. After coating the wafer W in the spin coating device 120, the wafer W may be transported to a baking device 161 and a temperature regulation device 170 prior to being delivered to the metrology unit 20. The metrology unit 20 has an outer wall 21, which may be sealed. The wafer W is delivered to the metrology unit 20 and may be supported on the wafer support 22 during processing.

A thickness measurement tool 23 of the metrology unit 20 is configured to measure a thickness of the layer 34 on the wafer W in a profile taken, for example, across a diameter of the wafer W. The thickness profile of layer 34 represents point-by-point thickness data mapped as a function of position on a top surface of layer 34. The data in the thickness profile is generated at a sufficient number of discrete positions to map the layer 34 across the diameter. The data generated by the thickness measurement is then sent to the processing unit 24, which is connected between the metrology unit 20, the spin coating device 120 the temperature regulation device 152, and the baking device 161. The thickness measurement tool 23 may generate the data by optical digital profiling (ODP) or other techniques understood by a person having ordinary skill in the art.

The processing unit 24 may be composed of a processor 25, a volatile memory 26, and a nonvolatile memory 27. A 1-D profile of the thickness of layer 34 created from the diameter measurement data from the metrology unit 20 may be sent and stored in the volatile memory 26 of the processor unit 24 as the processor 25 determines, by use of an analysis engine, if the diameter measurements are within the wafer specification. More specifically, the processor 25 determines an average thickness and standard deviation from the average thickness based upon the 1-D profile. The processor unit 24 may then adjust operational parameters of the spin coating device 120, for example, and send the adjustments to the controller 16. As shown in FIG. 4, the processing unit 24 may also be electrically connected to a temperature regulation device 160. The processing unit 24 may communicate with a temperature controller 32, which in turn adjusts the temperature of a chill plate 31 in the temperature regulation device 160. The processing unit 24 may also be electrically connected to other components of the coating/developing system 100, the heating and baking devices 155-158, 161-169, 174-179 to adjust operational parameters related to bake or cool time and temperature.

The processing unit 24 may display instructions to an operator of the coating/developing system 100 directing the operator to make adjustments to these other components, which may have an influence on the spin coating process of the spin coating device 120. For example, the temperature regulation devices 150,152-154,160, 170-173 may have operational parameters that may automatically adjust the temperature of the chill plate while other operational parameters may be adjustable by the operator. Similarly, the heating and baking devices 155-158, 161-169, 174-179, may have an exhaust port to remove any waste product or impurities produced from the coating 31 on the topside 30 of the wafer W during the heating process. The exhaust port may have an exhaust rate that may adjustable by the operator.

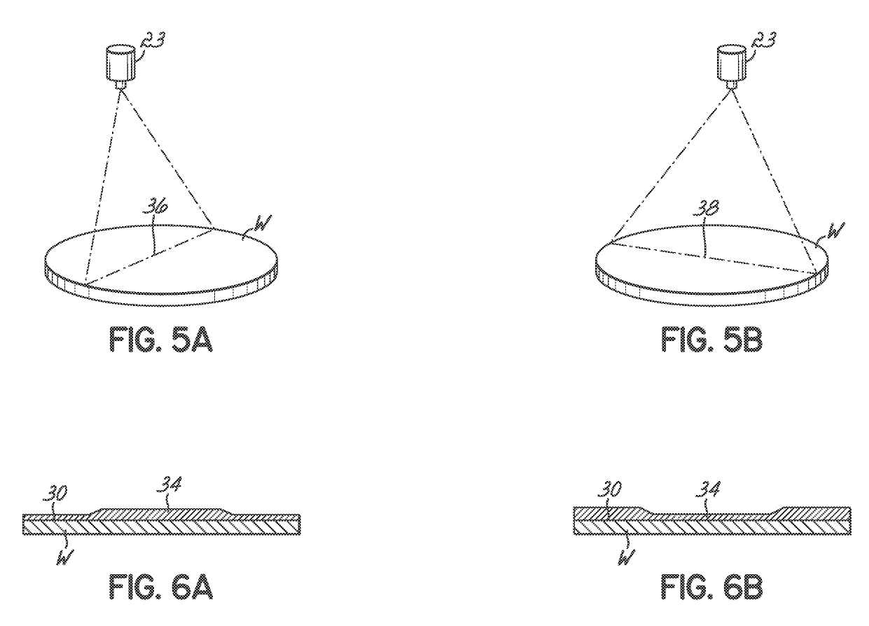

In order to ensure accurate coating measurements, the thickness measurement tool 23 may measure the thickness of the coating along multiple diameters of the wafer, creating multiple 1-D profiles, as shown in FIGS. 5A and 5B. In one embodiment, two diameter measurements creating two 1-D profiles 36, 38 may be made by the thickness measurement tool 23 of the metrology unit 20. Both 1-D profiles 36, 38 may then be sent to the processing unit 24 for analysis.

The suction port on the spin chuck 14, in some embodiments, may act as a heat sink causing a temperature gradient across the wafer W affecting the thickness of the coating on the wafer, as can be seen in the examples in FIGS. 6A and 6B in which differences in thickness are exaggerated for purposes of illustration. For example, in FIG. 6A, the coating 31 deposited on the topside 30 of wafer W is thicker in the regions that correspond spatially to the location of the suction port of the spin chuck 14, which holds the wafer W in place during the spin coating process. In other cases, the suction port of the spin chuck 14 may have the opposite effect, as shown in FIG. 6B, where the coating 32 deposited on the topside 30 of wafer W is thinner in the area immediately above the suction port of the spin chuck 14.

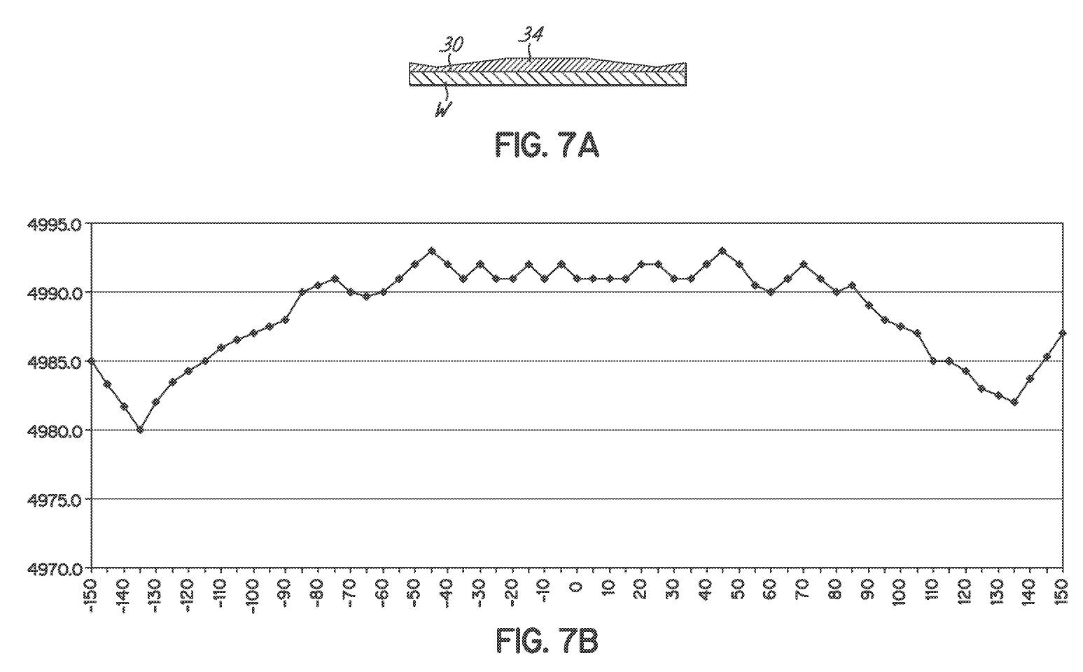

An exemplary coating that is outside of the wafer specification may be seen in FIG. 7A. The coating 33 deposited on the topside 30 of wafer W shows a non-uniform coating thickness thicker in the center tapering down and then again slightly thicker toward the edges. The graph shown in FIG. 7B, illustrates the 1-D profile obtained from the diameter measurement data made by the thickness measurement tool 23 of the metrology unit 20, which may be sent to the processing unit 24 for analysis. After analysis of the 1-D profile is made by the processing unit 24, parameters that directly influence the coating thickness may be automatically adjusted by the controller to correct the non-uniformity of the coating across the wafer W. These parameters include, but are not limited to a resist temperature, chill plate temperature, resist dispense rate, angular velocity of the spin chuck, resist dispense volume, dispense time, reflow step time, or reflow step angular velocity. Historical data acquired from previous measurements or parameter sensitivities obtained from a Design of experiment may be used as part of the analysis engine executing in the processing unit 24 to adjust the parameters, optimizing coating thickness on wafer W.

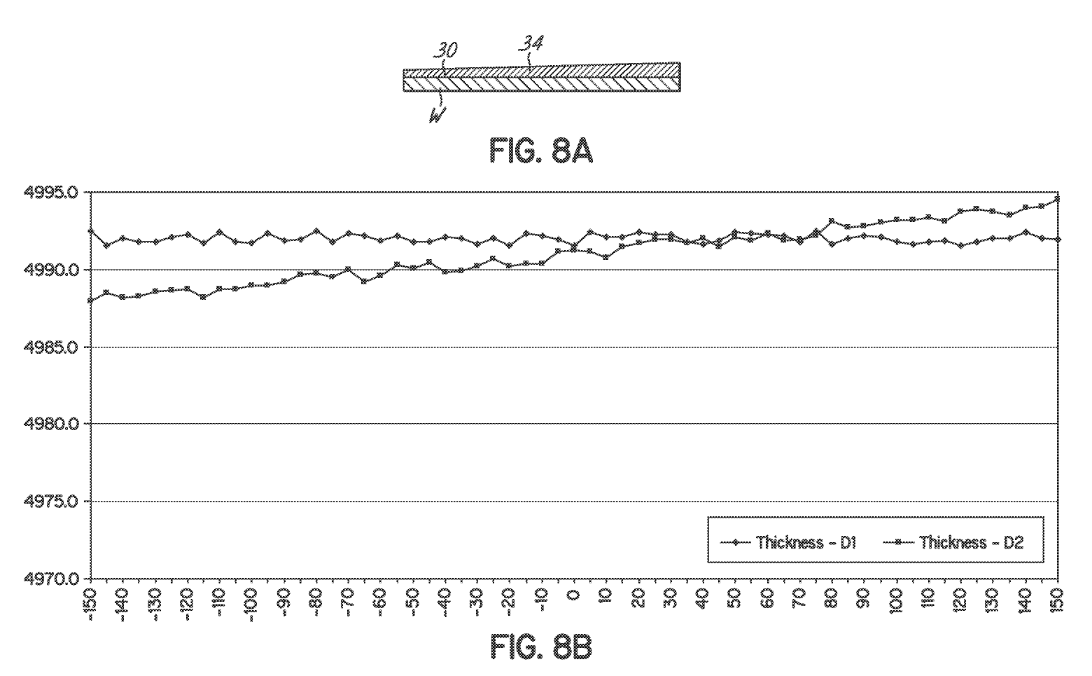

Another example of a non-uniform coating may be seen in FIG. 8A. The layer 34 deposited on the topside 30 of wafer W may be biased toward one side of the wafer such that a 1-D profile from a single diameter measurement may not detect the wafer non-uniformity. As can be seen in the graph in FIG. 8B, a 1-D profile of one diameter thickness indicates a fairly uniform coating thickness across the diameter where a second 1-D profile illustrates a non-uniformity from one edge of the wafer across the diameter to the second edge of the wafer. One reason to take multiple diameter measurements to create multiple 1-D profiles in some embodiments may be to detect this type of non-uniformity in the wafer. To keep the number of diameter measurements to a minimum, measurements may be taken approximately 90 degrees apart from one another in order to capture non-uniformities across the wafer.

In addition to the parameters mentioned above, other parameters of the coating/developing system 100 may have an indirect affect on the wafer thickness. These parameters of the coating/developing system 100 may take longer to stabilize and may not be well suited for automatic adjustments. The system parameters may include parameters such as a coater exhaust, hot plate exhaust, temperature, airflow in the cup, humidity or water content in the cup. While some of these parameters may not be able to be adjusted automatically by the processing unit 24 through the controller 16, in some embodiments, the processing unit 24 may include a display 28 to display instructions directed to an operator of the coating/developing system to adjust the parameter, for example, manually adjusting the humidity with a humidity control device 93 coupled to the processing space 19 in the spin coating device 120.

The processor unit 24, in one embodiment, may utilize a historical database containing data related to the parameters to dial into a best case faster. Given a statistical relevant amount of historical data from a broad selection of chemistries, significant parametric tendencies may be calculated and understood to generate a thickness uniformity model engine. The historical knowledge base may originate from past experiences of a skilled engineer for a given chemistry and its relative parameter sensitivities. This information may be entered into the model engine, which may refine the data during future optimization cycles. If no historical data exists for a given chemistry, the thickness uniformity model engine may use data from similar chemistries to adjust parameters, while building a new knowledge base for the new chemistry to be used in later processing.

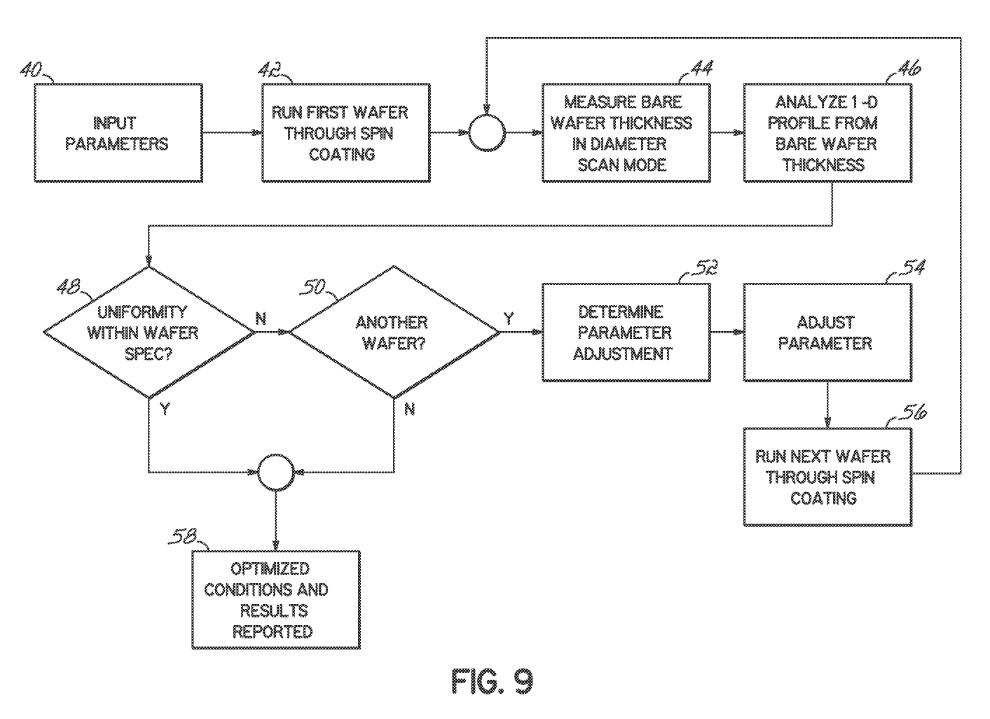

FIG. 9 illustrates one embodiment to optimize coating thickness. A set of input parameters for the controller 16 of the spin coating device 120 may be determined in block 40. In block 42, the spin coating process is run on a first wafer. The spin coating process may contain multiple steps that prepare and coat the wafer W. For example, during a single a coating process, the wafer W may be delivered to baking units 155-158 for an adhesion step and then sent to a pre-coating chill in temperature regulation devices 152-154. The wafer W may then be delivered to a spin coating device 120-122 to receive a coating of liquid spin-on material. The wafer W may then be delivered to a baking unit 161-164 for a pre-exposure bake. The pre-exposure bake at least partially cures the spin-on material in the coating or layer of liquid spin-on material. After the bake, the wafer W may be delivered to a temperature regulation device 170-173 where the temperature of the wafer W and the layer 34 deposited on the topside 30 of the wafer W are cooled, completing the coating process. After being coated, the wafer is transferred to the metrology unit 20 where, in block 44, a bare wafer thickness measurement is made in a diameter scan mode. The one-dimensional profile from the bare wafer thickness is sent to the processing unit 24 in block 46 for analysis automatically and without human intervention. If the uniformity of the coating on the wafer W is within the wafer specification (yes branch of decision block 48), then the optimized conditions and results of the parameters are reported in block 58.

If the uniformity of the coating is not within the wafer specification (no branch of decision block 48) then a check for another wafer is performed. If all of the wafers W of the lot, typically 25, have been exhausted (no branch of decision block 50), then the parameters in current optimized conditions are reported in block 58. If another wafer W is available (yes branch of decision block 50), then the processing unit 24 determines an adjustment to at least one of the parameters in block 52 and the parameter is adjusted either automatically without human intervention when data is sent to the controller 16 in block 54 or with human intervention when the parameter is one that requires a longer time for stabilization. In the latter case, the processing unit 24 may display instructions on the display 28 directing an operator to adjust the parameter. Another wafer W is then selected and run through the spin coating process in block 56, which in turn is then sent to the metrology unit 20 for a bare wafer thickness measurement. The process continues until either the uniformity of the coating on the wafer W falls within the wafer specification or the lot of wafers is exhausted.

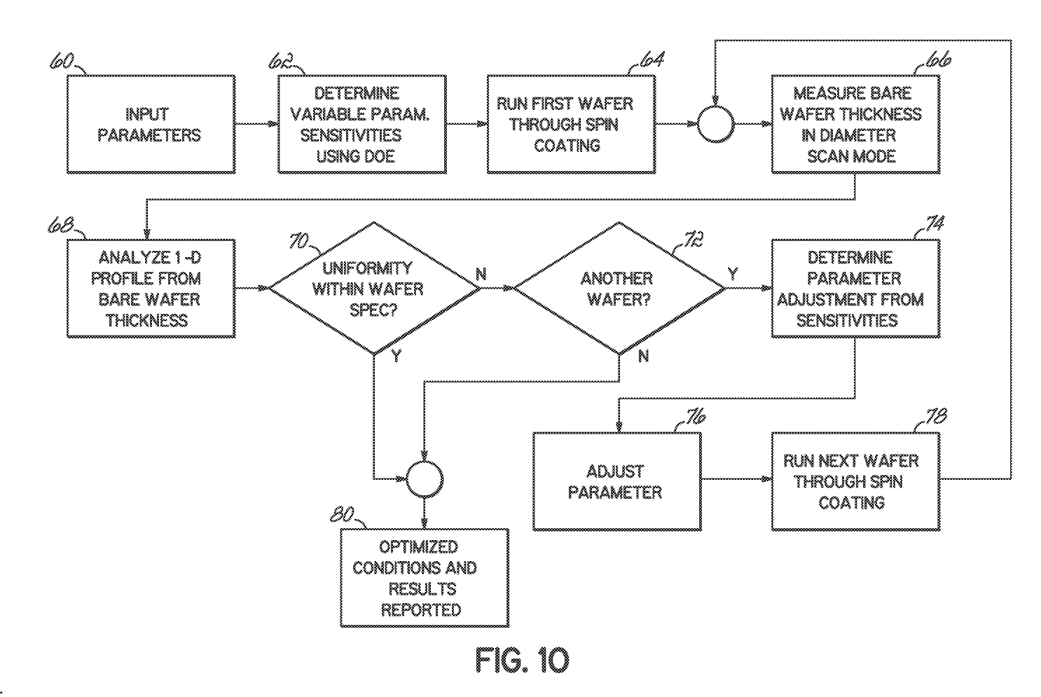

In an alternate embodiment and with reference to FIG. 10, the analytical engine in the processing unit 24 may be driven by a design of experiment. A design of experiment (DOE) is a structured, organized method for determining the relationship between factors (spin coating input parameters) affecting a process and the output of that process (film coating thickness on the wafer). Design of experiment techniques analyze the effect of varying several variables simultaneously in order to get the most data with the fewest runs (each run generates the result from and the set values of the variables being studied) while capturing interaction effects between the variables being studied. Designed experiments typically rely on random test runs. The runs may be in a random order to avoid introducing bias into the results.

DOE may be utilized in the processing unit 24, as shown in the flow chart in FIG. 10. Input parameters for the controller 16 are determined in block 60. In block 62, the variable parameter sensitivities are determined using design of experiments. A first wafer W is then run through the spin coating process in block 64, which may contain steps similar to the spin coating process described for the embodiment in FIG. 9 above. The pre-exposure bake at least partially cures the spin-on material in the coating or layer of liquid spin-on material. The wafer W is transferred to metrology unit 20 and, in block 66, a bare wafer thickness measurement is made in the diameter scan mode of the metrology unit. The one-dimensional profile data from the bare wafer thickness measurement is sent to the processing unit 24 for automatic analysis without human intervention in block 68. If the uniformity of the coating on the wafer W is within the wafer specification (yes branch of decision block 70), then the optimized conditions and the results are reported in block 80.

If the uniformity of the coating is not within the wafer specification (no branch of decision block 70), then a check is made for another wafer W. If another wafer w is not available (no branch of decision block 72) because all of the wafers W in the lot have been exhausted, then the optimized conditions and the results at this point are reported in block 80. If another wafer W is available (yes branch of decision block 72), then an adjustment to at least one of the parameter is determined by the parameter sensitivities that are calculated by the design of experiments in block 74. Adjustments are made to the parameters in block 76, which are then sent to the controller 16 to be ready for the next spin coating process. The adjustments may be communicated directly to the controller 16 or may be communicated to an observer via display. A new wafer W is selected and run through the spin coating process in block 78 after which it is transferred to the metrology unit 20 for a thickness measurement. The process continues until either a coating with a uniformity that is within the wafer specification is reached or the lot of wafers is exhausted.

Using an automated process that utilizes either historical data or DOE may allow field engineers who are installing and setting up the coating/developing systems 100 to be able to configure those systems to produce uniform coatings on wafers W in a shorter time frame than has been done traditionally in the past. In addition to the automated parameter adjustments, field engineers may not need to be experts in order to determine which of the coating/developing system 100 parameters to adjust to provide coating uniformity on the wafers W. In this particular illustrated embodiment, the metrology unit 20 was shown to be integrated with the coating/developing system 100. In other embodiments, the metrology unit may be off-line. Likewise, while historical data stored in a database or design of experiments was used in the analytical engine executing in the processing unit 24, any numerical methods appropriate for analyzing the one-dimension profile and comparing it against the wafer specification to determine parameter adjustments may be used.

While the invention has been illustrated by a description of various embodiments and while these embodiments have been described in considerable detail, it is not the intention of the applicants to restrict or in any way limit the scope of the appended claims to such detail. Additional advantages and modifications will readily appear to those skilled in the art. The invention in its broader aspects is therefore not limited to the specific details, representative apparatus and method, and illustrative examples shown and described. Accordingly, departures may be made from such details without departing from the spirit or scope of applicant's general inventive concept.

What is claimed is:

1. An apparatus for applying a fluid spin-on material on a surface of first and second substrates, the apparatus comprising:
a spin coating device configured to dispense the fluid spin-on material on the surface of the first substrate to apply a first layer and to dispense the fluid spin-on material on the surface of the second substrate to apply a second layer;
a metrology tool configured to measure a first thickness profile of at least the first layer and to generate data representing the first thickness profile; and
a processing unit electrically coupled with the metrology tool, the processing unit configured to analyze the data received from the metrology unit and to determine a variation in the first thickness profile, and the processing unit further configured to automatically determine an adjustment to an operational parameter of the spin coating device predicted to reduce a variation in a second thickness profile of the second layer subsequently applied by the spin coating device on the surface of the second substrate.

2. The apparatus of claim 1 wherein the spin coating device comprises a supply of the fluid spin-on material, and a dispenser coupled in fluid communication with the supply for receiving the fluid spin-on material, the dispenser configured to dispense the fluid spin-on material onto the surface of the first and second substrates.

3. The apparatus of claim 2 wherein the dispenser and the supply are configured to dispense the fluid spin-on material onto the surface of the first and second substrates at a dispense rate representing the operational parameter.

4. The apparatus of claim 2 wherein the dispenser and the supply are configured to dispense a volume of the fluid spin-on material onto the surface of the first and second substrates, and the operational parameter is the volume.

5. The apparatus of claim 2 wherein the dispenser and the supply are configured to dispense the fluid spin-on material onto the surface of the first and second substrates over a dispense time representing the operational parameter.

6. The apparatus of claim 2 wherein at least one of the dispenser and the supply includes a heater configured to heat the fluid spin-on material to a dispense temperature representing the operational parameter.

7. The apparatus of claim 2 wherein the spin coating device further comprises a cup bounding a processing space, and a substrate support configured to support each of the first and second substrates within the processing space, the substrate support configured to rotate relative to the cup, and the substrate support arranged relative to the cup such that the cup captures a majority of the fluid spin-on material ejected from the surface of first and second substrates when each of the first and second substrates is supported and rotated within the processing space by the substrate support relative to the cup.

8. The apparatus of claim 7 wherein the spin coating device further comprises a drive mechanism coupled with the substrate support, the drive mechanism configured to rotate the substrate support with an adjustable angular velocity representing the operational parameter.

9. The apparatus of claim 7 wherein the cup includes an exhaust port communicating with the processing space, and the spin coating device further comprises an exhaust unit coupled by the exhaust port with the processing space, the exhaust unit operative to remove gaseous species from the processing space via the exhaust port with an adjustable exhaust rate representing the operational parameter.

10. The apparatus of claim 7 wherein the cup includes a drain port communicating with the processing space, and the spin coating device further comprises a drain unit coupled by the drain port with the processing space, the drain unit operative to remove liquid spin-on material from the processing space that is ejected from the first and second substrates and collected by the cup through the drain port with an adjustable drain rate representing the operational parameter.

11. The apparatus of claim 7 wherein the processing space contains a gaseous atmosphere with a water vapor content representing the operational parameter, and the spin coating device further comprises a humidity control device coupled with the processing space, the humidity control device operative to adjust the water vapor content.

12. The apparatus of claim 1 wherein the processing unit is configured to numerically analyze the data received from the metrology unit utilizing historical data to determine the adjustment to the operational parameter.

13. The apparatus of claim 1 wherein the processing unit is configured to numerically analyze the data received from the metrology unit utilizing a design of experiment model to determine the adjustment to the operational parameter.

14. The apparatus of claim 1 wherein the processing unit is electrically coupled with the spin coating device, the processing unit configured to send an electrical signal to the spin coating device for performing the adjustment to the operational parameter without human intervention.

15. An apparatus for applying a fluid spin-on material on a surface of first and second substrates, the apparatus comprising:
a spin coating device configured to dispense the fluid spin-on material on the surface of the first substrate to apply a first layer and to dispense the fluid spin-on material on the surface of the second substrate to apply a second layer;
a temperature regulation device configured to heat or cool the first and second substrates thereby adjusting a temperature of the respective one of the first and second layers;
a baking device configured to elevate the temperature of the first and second substrates thereby adjusting the temperature of the respective one of the first and second layers;
a metrology tool configured to measure a first thickness profile of at least the first layer and to generate data representing the first thickness profile; and
a processing unit electrically coupled with the metrology tool, the processing unit configured to analyze the data received from the metrology unit and to determine a variation in the first thickness profile, and the processing unit further configured to automatically determine an adjustment to an operational parameter of at least one of the spin coating device, the temperature regulation device, or the baking device predicted to reduce a variation in a second thickness profile of the second layer subsequently formed by the spin coating device on the second substrate.

16. The apparatus of claim 15 wherein the processing unit is electrically coupled with the spin coating device, the processing unit configured to send an electrical signal to the spin coating device for performing the adjustment to the operational parameter without human intervention.

17. The apparatus of claim 15 wherein the processing unit is electrically coupled with the temperature regulation device, the processing unit configured to send an electrical signal to the temperature regulation device for performing the adjustment to the operational parameter without human intervention.

18. The apparatus of claim 15 wherein the processing unit is electrically coupled with the baking device, the processing unit configured to send an electrical signal to the baking device for performing the adjustment to the operational parameter without human intervention.

19. The apparatus of claim 15 wherein the temperature regulation device further comprises a chill plate and a temperature controller, the chill plate adapted to receive and cool the first substrate, the chill plate having an operating temperature representing the operational parameter, and the temperature regulation device electrically coupled with the processing unit and adapted to adjust the operating temperature of the chill plate representing the operational parameter.

20. The apparatus of claim 15 further comprising:
a display electrically coupled with the processing unit, the processing unit generating and sending signals to the display effective to visually indicate the operational parameter and the adjustment to the operational parameter.

21. The apparatus of claim 15 wherein the baking device has an exhaust and wherein a waste product produced from the first layer during a bake process is discharged through the exhaust at an exhaust rate representing the operational parameter.

22. A method for applying a fluid spin-on material on a surface of first and second substrates, the method comprising:
regulating a temperature of the first substrate;
applying a first layer of the spin-on material on the surface of the first substrate while the first substrate is approximately at the regulated temperature;
elevating the temperature of the first substrate to at least partially cure the spin-on material in the first layer;
measuring a first thickness profile of the first layer after the spin-on material in the first layer is at least partially cured;
determining a variation in the first thickness profile;
automatically determining an adjustment to an operational parameter that is predicted to reduce the variation in the first thickness profile; and
making the adjustment to the operational parameter to reduce a variation in a second thickness profile of a second layer of the spin-on material subsequently applied on the surface of the second substrate.

23. The method of claim 22 wherein making the adjustment to the operational parameter further comprises:
generating an electrical signal representing the adjustment;
communicating the electrical signal to a device that regulates the temperature of the second substrate before the second layer is applied, applies the second layer of the spin-on material on the second substrate, or elevates the temperature of the second substrate after the second layer is applied; and
adjusting the operational parameter of the device to reflect the communicated electrical signal.

24. The method of claim 22 wherein making the adjustment to the operational parameter further comprises:
generating an electrical signal representing the adjustment;
communicating the electrical signal to a display;
visually indicating the operational parameter and the adjustment to the operational parameter on the display; and
manually adjusting the operational parameter of a device that regulates the temperature of the second substrate before the second layer is applied, applies the second layer of the spin-on material on the second substrate, or elevates the temperature of the second substrate after the second layer is applied to reflect the visually indicated adjustment.

25. The method of claim 22 wherein automatically determining the adjustment to the operational parameter further comprises:
numerically analyzing the data received from the metrology unit utilizing parameter sensitivities derived from a design of experiment model to determine the adjustment to the operational parameter.

26. The method of claim 22 further comprising:
measuring a second thickness profile of the first layer;
determining a variation in the second thickness profile; and
automatically determining the adjustment to the operational parameter of a device that regulates the temperature of the second substrate before the second layer is applied, applies the second layer of the spin-on material on the second substrate, or elevates the temperature of the second substrate after the second layer is applied for reducing the variation in the second thickness profile.

27. The method of claim 22 wherein regulating the temperature of the first substrate further comprises:
placing the first substrate on chill plate that establishes the temperature of the first substrate.

28. The method of claim 27 wherein the operational parameter is a chill temperature of the chill plate, and making the adjustment to the operational parameter further comprises:
automatically adjusting the chill temperature at which the chill plate is operated to regulate a temperature of the second substrate before the second layer is applied.

29. The method of claim 27 wherein the operational parameter is a chill time over which the chill plate cools the second substrate, and making the adjustment to the operational parameter further comprises:
automatically adjusting the chill time to adjust the chill temperature of the second substrate before the second layer is applied.

30. The method of claim 22 wherein a spin coating device applies the second layer of the spin-on material to the surface of the second substrate, the spin coating spin coating device having a cup bounding a processing space, a dispenser adapted to dispense the spin-on material onto the surface of the second substrate, and a substrate support configured to support and rotate the second substrate within the processing space relative to the cup.

31. The method of claim 30 wherein the operational parameter is a dispense temperature of spin-on material, and making the adjustment to the operational parameter further comprises:
automatically adjusting the dispense temperature of the spin-on material dispensed by the spin coating device onto the surface of the second substrate for applying the second layer.

32. The method of claim 30 wherein the operational parameter is an angular velocity at which the substrate support rotates the second substrate, and making the adjustment to the operational parameter further comprises:
automatically adjusting the angular velocity at which the second substrate is rotated while the spin-on material is dispensed onto the surface of the second substrate for applying the second layer.

33. The method of claim 30 wherein the operational parameter is an angular velocity at which the substrate support rotates the second substrate, and making the adjustment to the operational parameter further comprises;
automatically adjusting the angular velocity at which the second substrate is rotated to reflow the spin-on material of the second layer across the surface of the second substrate for applying the second layer.

34. The method of claim 30 wherein the operational parameter is a dispense rate of the spin-on material, and making the adjustment to the operational parameter further comprises:
automatically adjusting the dispense rate at which the spin-on material is dispensed by the spin coating device onto the surface of the second substrate for applying the second layer.

35. The method of claim 30 wherein the operational parameter is a dispense volume of the spin-on material, and making the adjustment to the operational parameter further comprises:
adjusting the dispense volume of spin-on material dispensed by the spin coating device onto the surface of the second substrate for applying the second layer.

36. The method of claim 30 wherein the operational parameter is a reflow time of the spin-on material in the second layer, and making the adjustment to the operational parameter further comprises:
adjusting the reflow time over which the second substrate is rotated to reflow the second layer across the surface of the second substrate.

37. The method of claim 30 wherein the operational parameter is a temperature in the cup, and making the adjustment to the operational parameter further comprises:
automatically adjusting the cup temperature at which the spin coating device is operated to dispense the spin-on material to the surface of the second substrate for applying the second layer.

38. The method of claim 30 wherein the cup contains a gaseous atmosphere and a humidity control device, the operational parameter is a water vapor content in the gaseous atmosphere, and making the adjustment to the operational parameter further comprises:
adjusting the water vapor content of the gaseous atmosphere when dispensing the spin-on material to the surface of the second substrate for applying the second layer.

39. The method of claim 30 wherein the cup includes an exhaust port and the operational parameter is an exhaust rate of the exhaust port, and making the adjustment to the operational parameter further comprises:
adjusting the exhaust rate of the exhaust port when dispensing the spin-on material to the surface of the second substrate for applying the second layer.

40. The method of claim 22 wherein a baking device elevates the temperature of the first substrate, the baking device having a hotplate and an exhaust port.

41. The method of claim 40 wherein the operational parameter is a temperature of the hotplate, and making the adjustment to the operational parameter further comprises:
automatically adjusting the temperature of the hotplate when elevating a temperature of the second substrate.

42. The method of claim 40 wherein the operational parameter is a bake time over which the second substrate is heated by the hotplate, and making the adjustment to the operational parameter further comprises:
automatically adjusting the bake time of the second substrate.

43. The method of claim 40 wherein the operational parameter is an exhaust rate of the exhaust port, and making the adjustment to the operational parameter further comprises:
adjusting the exhaust rate of the exhaust port when elevating a temperature of the second substrate.
